(19) United States
(12) Patent Application Publication
(10) Pub. No.: US 2017/0063465 A1
(43) Pub. Date: Mar. 2, 2017

(54) TECHNIQUES FOR REDUCING THE FOOTPRINT OF A MULTI-CHANNEL TRANSMITTER OPTICAL SUBASSEMBLY (TOSA) WITHIN AN OPTICAL TRANSCEIVER HOUSING

(71) Applicant: Applied Optoelectronics, Inc., Sugar Land, TX (US)

(72) Inventors: Kaisheng LIN, Sugar Land, TX (US); Hao-Hsiang LIAO, Sugar Land, TX (US); Yong-Xuan LIANG, Stafford, TX (US)

(21) Appl. No.: 15/204,174

(22) Filed: Jul. 7, 2016

Related U.S. Application Data
(63) Continuation-in-part of application No. 14/837,993, filed on Aug. 27, 2015.

(51) Int. Cl. H04B 10/40; G01J 1/02; H04B 10/58; H01S 5/022

(52) U.S. Cl. CPC H04B 10/40; H01S 5/02212; G01J 1/0271; H04B 10/58

(57) ABSTRACT

In accordance with an embodiment, a transmitter optical subassembly (TOSA) having one or more recessed mounting regions is disclosed in order to decrease the overall footprint of the TOSA within an optical transceiver housing. The TOSA includes a housing having at least a first sidewall and a second sidewall disposed on opposite sides of the housing relative to each other. The housing further includes a first step portion defined by the first sidewall and a first recessed mounting region extending from about the first step portion along the longitudinal axis towards the second end. The first recessed mounting region is defined by an external surface of the first sidewall that is offset from a surface defining the first step portion by a first offset distance. The first recessed mounting region includes at least one sidewall opening to couple to optical component assemblies.

### CROSS-REFERENCE TO RELATED APPLICATIONS

This Application is a continuation in part of co-pending U.S. application Ser. No. 14/837,993 ('993 Application) filed on Aug. 27, 2015, titled “Multi-Channel Transmitter Optical Subassembly (TOSA) With Opposing Placement of Transistor Outline (TO) Can Laser Packages,” which is herein incorporated by reference in its entirety.

### TECHNICAL FIELD

The present disclosure relates generally to optical subassemblies, and more particularly, to a transmitter optical subassembly (TOSA) housing having a stepped-profile along one or more sidewalls to provide a recessed mounting region to couple to optical assemblies, such as laser diode assemblies, and limit the overall footprint of the TOSA within an optical transceiver housing.

### BACKGROUND INFORMATION

Optical transceivers are used to transmit and receive optical signals for various applications including, without limitation, internet data center, cable TV broadband, and fiber to the home (FTTH) applications. Optical transceivers provide higher speeds and bandwidth over longer distances, for example, as compared to transmission over copper cables. The desire to provide higher speeds in smaller optical transceiver modules for a lower cost has presented challenges, for example, with respect to maintaining optical efficiency (power), thermal management, insertion loss, and manufacturing yield.

### BRIEF DESCRIPTION OF THE DRAWINGS

These and other features and advantages will be better understood by reading the following detailed description, taken together with the drawings wherein:

FIG. 1A is a side plan view of one approach to a multi-channel TOSA with multiple TO can laser packages.

FIG. 1B is a side plan view of another approach to a multi-channel TOSA with multiple opposing TO can laser packages.

FIG. 2 schematically illustrates an embodiment of an optical transceiver including a multi-channel TOSA and multi-channel receiver optical subassembly (ROSA).

FIG. 3 is a perspective view of an example small form-factor (SFF) pluggable transceiver with a multi-channel TOSA including TO can laser packages and a multi-channel ROSA, in accordance with an embodiment of the present disclosure.

FIG. 4A is a cross-sectional view of an example multi-channel TOSA housing shown in FIG. 3, in accordance with an embodiment of the present disclosure.

FIG. 4B is an example plan view of the multi-channel TOSA housing shown in FIG. 3, in accordance with an embodiment of the present disclosure.

FIG. 4C is side plan view of the multi-channel TOSA of FIG. 3, in accordance with an embodiment of the present disclosure.

FIG. 4D is a cross-sectional view of the multi-channel TOSA of FIG. 4C taken along the line A-A, in accordance with an embodiment of the present disclosure.

FIG. 5 shows an exploded view of the multi-channel TOSA of FIG. 3, in accordance with an embodiment of the present disclosure.

FIG. 6A shows a plan view of a first sidewall of the multi-channel TOSA of FIG. 3, in accordance with an embodiment of the present disclosure.

FIG. 6B shows a plan view of a second sidewall of the multi-channel TOSA of FIG. 3, in accordance with an embodiment of the present disclosure

### DETAILED DESCRIPTION

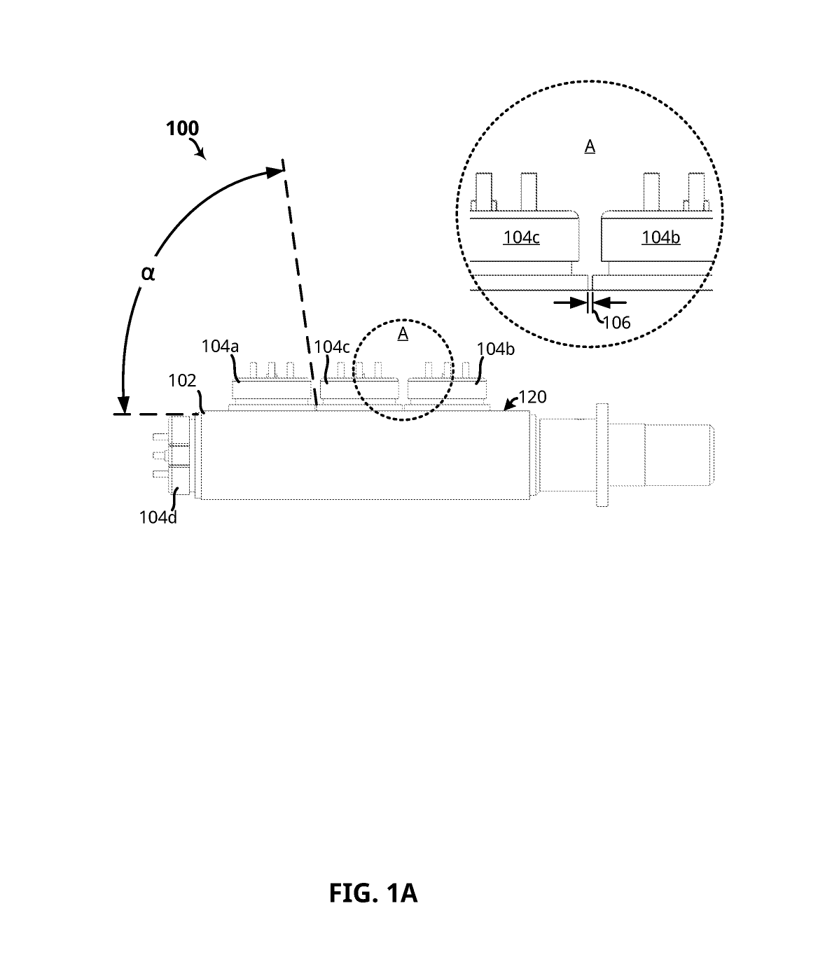

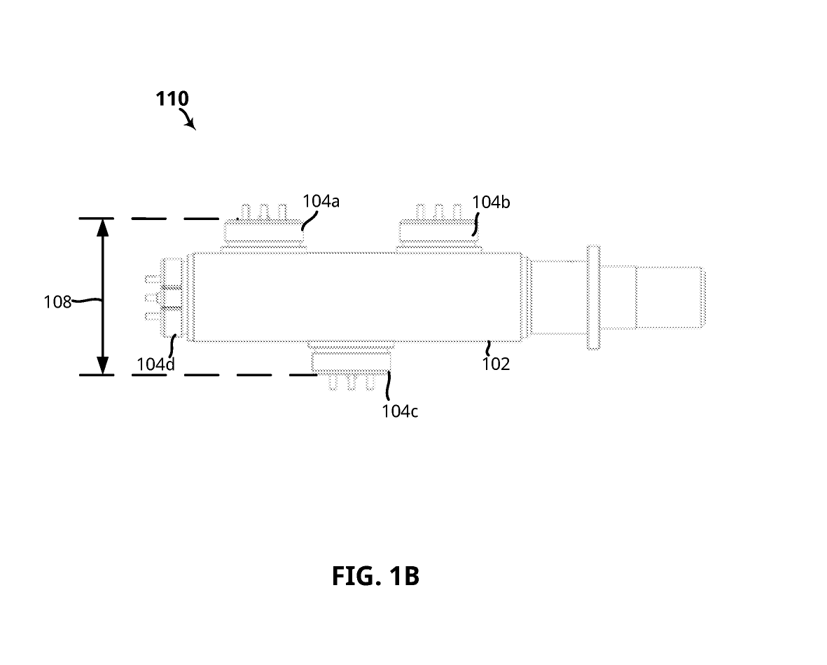

Some small form-factor (SFF) optical transceiver housings, such as SFF pluggable (SFFP) transceiver housings, include dimensions in the tens of millimeters or less, for example, and thus provide relatively constrained housings for associated transmitter optical subassemblies (TOSAs) and receiver optical subassemblies (ROSAs). Subassemblies designed to fit within such constrained housings can complicate manufacturing processes and present non-trivial issues. For example, TOSAs such as the TOSA shown in FIG. 1A, may include a relatively small dimension 106 between adjacent TO can laser packages (or assemblies) 104b and 104c. As shown, the multi-channel TOSA 100 includes four (4) TO can laser packages 104a-104d, three (3) of which are arranged coupled to a first sidewall 120 of the housing 102. However, post attachment alignment of TO can laser packages 104a-c using, for instance, a laser welding system may be complicated, error-prone, and time-consuming due to the relatively limited range of available approach angles a, which arise from the constraints imposed by the dimension 106. Therefore, in some TOSAs it may be desirable to have one or more optical assemblies coupled to the TOSA housing in an opposing configuration, such as shown in the example embodiment of FIG. 1B, which will be discussed in greater detail below. An example TOSA with an opposing TO can laser package configuration is also discussed in detail in co-pending '993 Application.

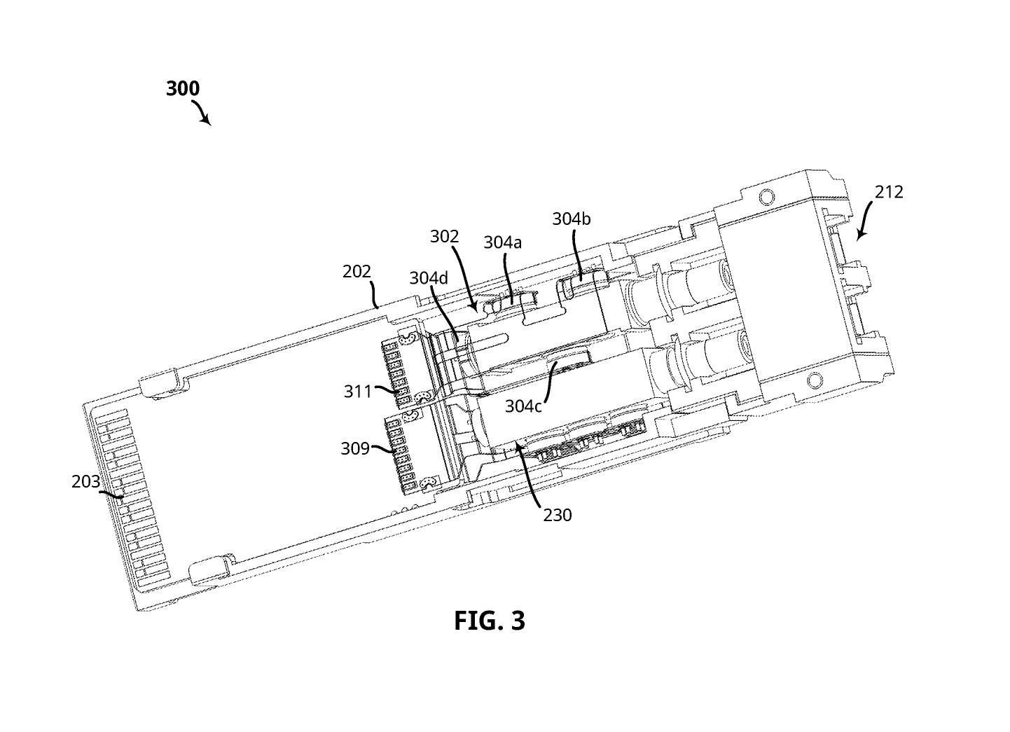

While such an opposing TO can configuration may provide various advantages, e.g., providing additional space for post-attachment alignment of the optical assemblies coupled to the TOSA housing via welding, it may also result in the overall footprint of the TOSA being increased relative to a TOSA having a non-opposing configuration, such as shown in the example TOSA 100 of FIG. 1A. For example, as shown in the SFFP transceiver housing of FIG. 3, a transmitter optical subassembly (TOSA) 302 is disposed in a first region of a cavity defined by the SFF housing 202, and a receiver optical subassembly (ROSA) 230 is disposed in a second region of the cavity defined by the SFF housing 202. The opposing configuration of the TOSA 302, and more particularly, the pins of the TO can laser package 304c extend toward and make contact with a surface of the ROSA 230. Such contact may result in operational interference between the TOSA 302 and the ROSA 230, e.g., resulting in an electrical short or RF interference, and may also further complicate attachment of associated circuitry to the pins of the TO laser package 304c, e.g., a flexible printed circuit board. Even in configurations without an opposing TO can configuration, TOSAs and other subassemblies may include footprints that complicate the design and manufacture of optical transceiver housings.

Thus, in accordance with an embodiment of the present disclosure, a TOSA having a housing with a stepped-profile along at least one sidewall to reduce the overall footprint of a TOSA is provided. In an embodiment, the TOSA includes a housing having a plurality of sidewalls, wherein a first sidewall of the plurality of sidewalls defines first and second step portions, and a first recessed mounting region disposed there between. The first and second step portions may also be described as shoulder portions. The first recessed mounting region includes at least a first and second sidewall opening for receiving and coupling to an optical assembly, such as a TO can laser assembly, a filter assembly, or a mirror assembly, just to name a few. A second sidewall of the plurality of sidewalls of the housing may also define third and fourth step portions and a second recessed mounting region disposed there between. The second sidewall may be disposed opposite the first sidewall and, by extension, the second recessed mounting region may oppose the first recessed mounting region. The second recessed mounting region includes at least a third sidewall opening for receiving an optical assembly. The third sidewall opening is positioned opposite the first and second sidewall openings, and is generally located at a mid-point between the first and second sidewall openings. As such, the optical assemblies are positioned within a respective recessed mounting region in a staggered and opposing configuration. Accordingly, the TOSA housing can include a reduced footprint along at least one dimension measured from an outer surface of the first recessed region to an outer surface of the second recessed region. Although various aspects and embodiments discussed herein include a TOSA housing having recessed regions disposed in an opposing fashion, this disclosure is not necessarily limited in this regard. For example, the TOSA housing may include recessed regions on any number of sidewalls including a single sidewall, multiple sidewalls, and multiple opposing sidewalls, depending on a desired configuration.

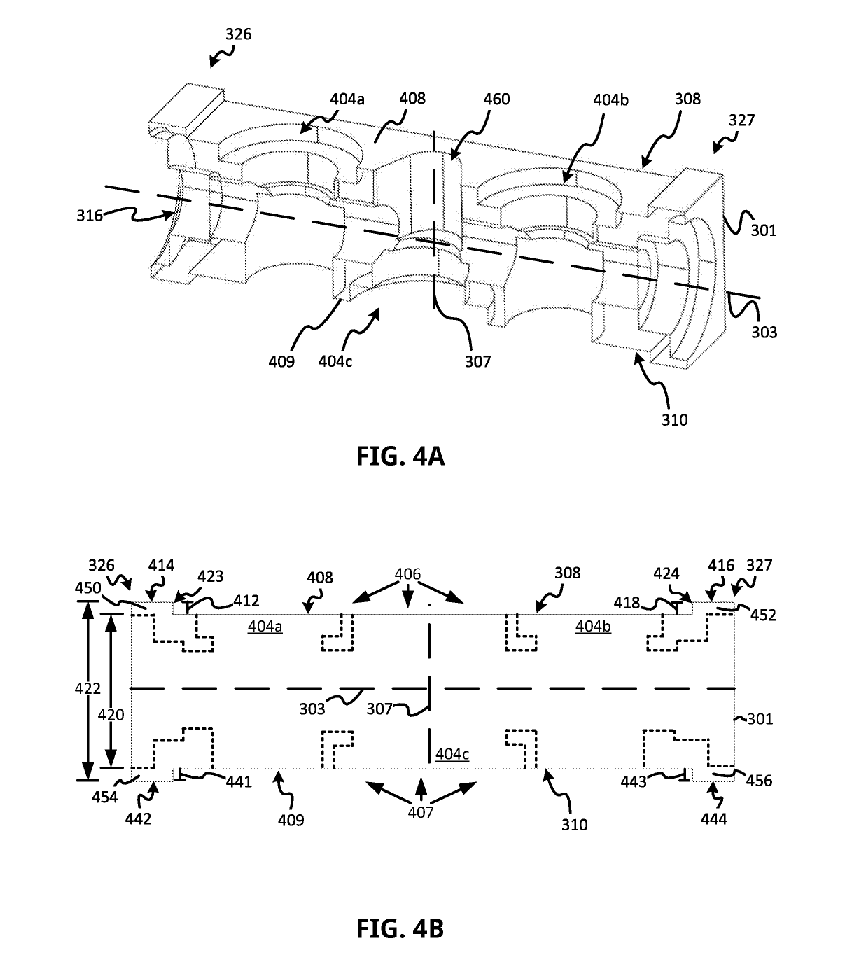

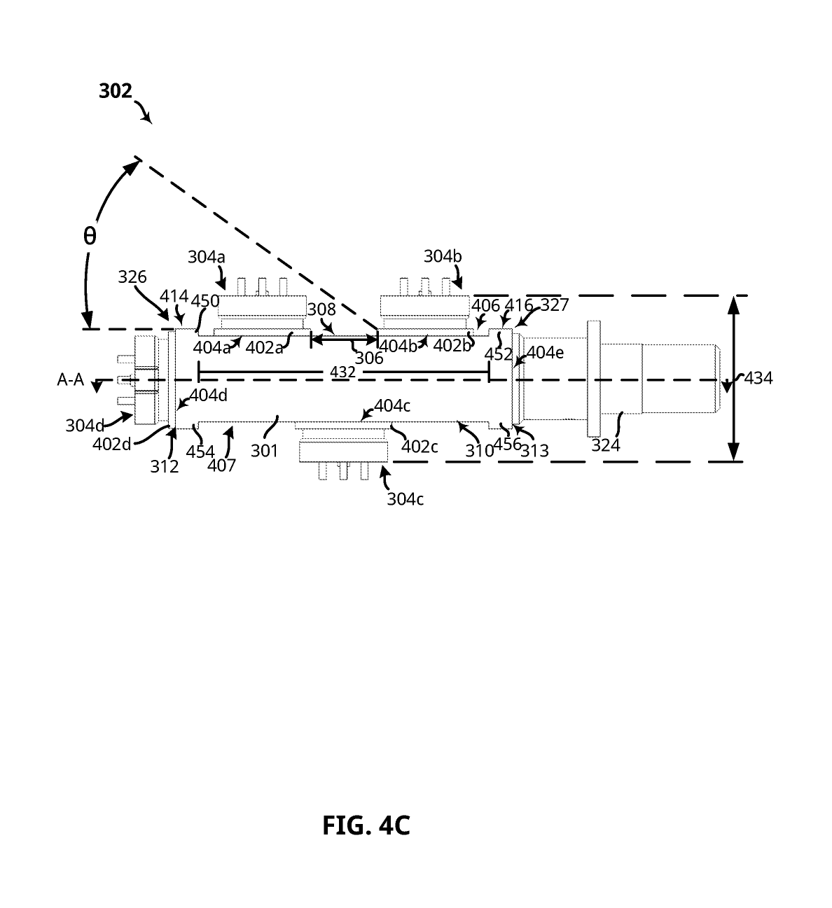

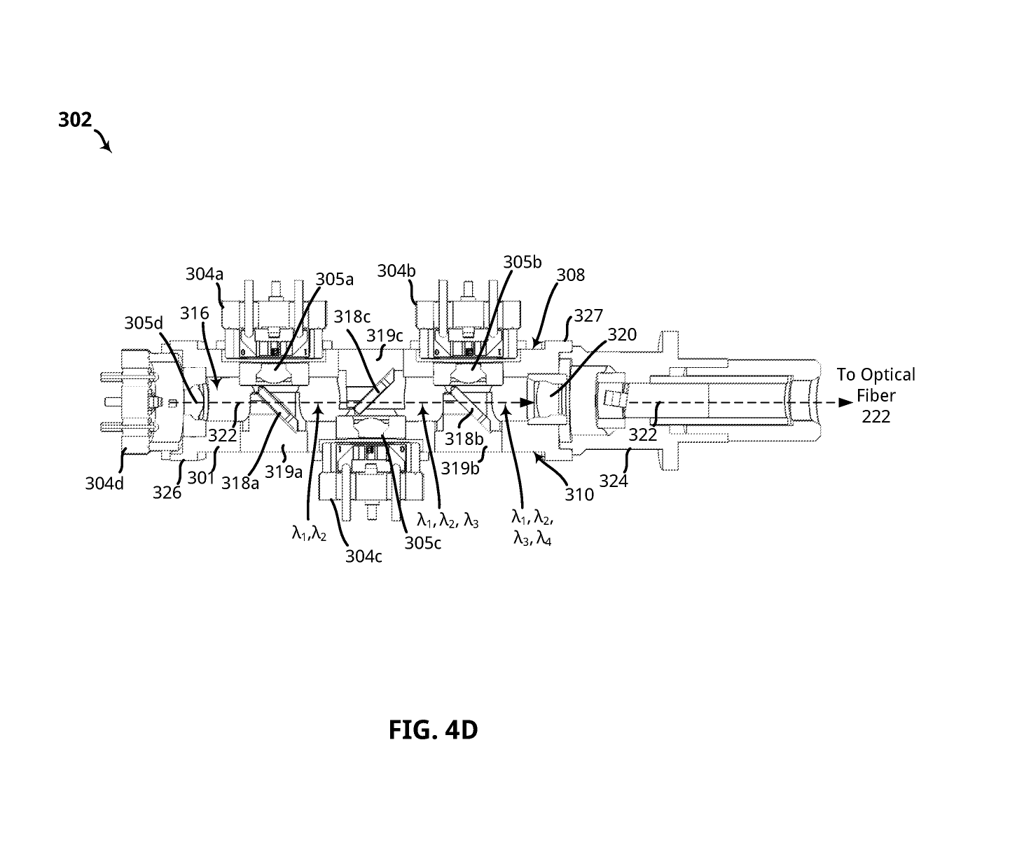

In any event, the inclusion of one or more recessed mounting regions in the TOSA housing advantageously allows for the overall footprint of the TOSA to be reduced relative to the extent of the recess. As will be discussed in further detail below, step portions associated with the one or more recessed mounting regions may also provide a suitable mounting point for optical assemblies to mount to sidewalls that adjoin the one or more sidewalls that provide recessed mounting regions. For instance, and as shown by the TOSA housing of FIG. 4C, the step portions 450 and 454 adjacent the recessed mounting regions 406 and 407, respectively, may advantageously allow for the fourth TO can laser assembly 304d to couple to the housing 301 of the TOSA 302. Therefore, although the staggered and opposing configuration may increase the overall footprint of the TOSA, e.g., by virtue of pins from TO can laser assemblies extending out from multiple sidewalls, the inclusion of one or more recessed mounting regions minimizes or otherwise reduces the magnitude of the increase in the overall footprint of the TOSA. Moreover, a TOSA housing having one or more recessed mounting regions, as variously disclosed herein, allows the same to have any number of TO can placement configurations, e.g., an opposing placement as shown in FIG. 1B, a non-opposing placement as shown in FIG. 1A, and so on, while comporting with the physical constraints of a particular optical transceiver housing.

While the present disclosure refers specifically to a TOSA including TO can laser packages, such a configuration is not intended to limit the present disclosure. A TO can laser package represents one suitable type of optical assembly that can be used herein and other optical assemblies including, for example, one or more, filters, mirrors, laser diodes, lenses, diffusers, polarizers, prisms, beam splitters, diffraction gratings, and other similar assemblies that may undesirably increase the footprint of an optical subassembly when coupled thereto may also be used. Furthermore, while the present disclosure primarily refers to a TOSA, this disclosure is equally applicable to, for example, a receiver optical subassembly (ROSA).

As used herein, “channel wavelengths” refer to the wavelengths associated with optical channels and may include a specified wavelength band around a center wavelength. In one example, the channel wavelengths may be defined by an International Telecommunication (ITU) standard such as the ITU-T dense wavelength division multiplexing (DWDM) grid. The term “coupled” as used herein refers to any connection, coupling, link or the like and “optically coupled” refers to coupling such that light from one element is imparted to another element. Such “coupled” devices are not necessarily directly connected to one another and may be separated by intermediate components or devices that may manipulate or modify such signals.

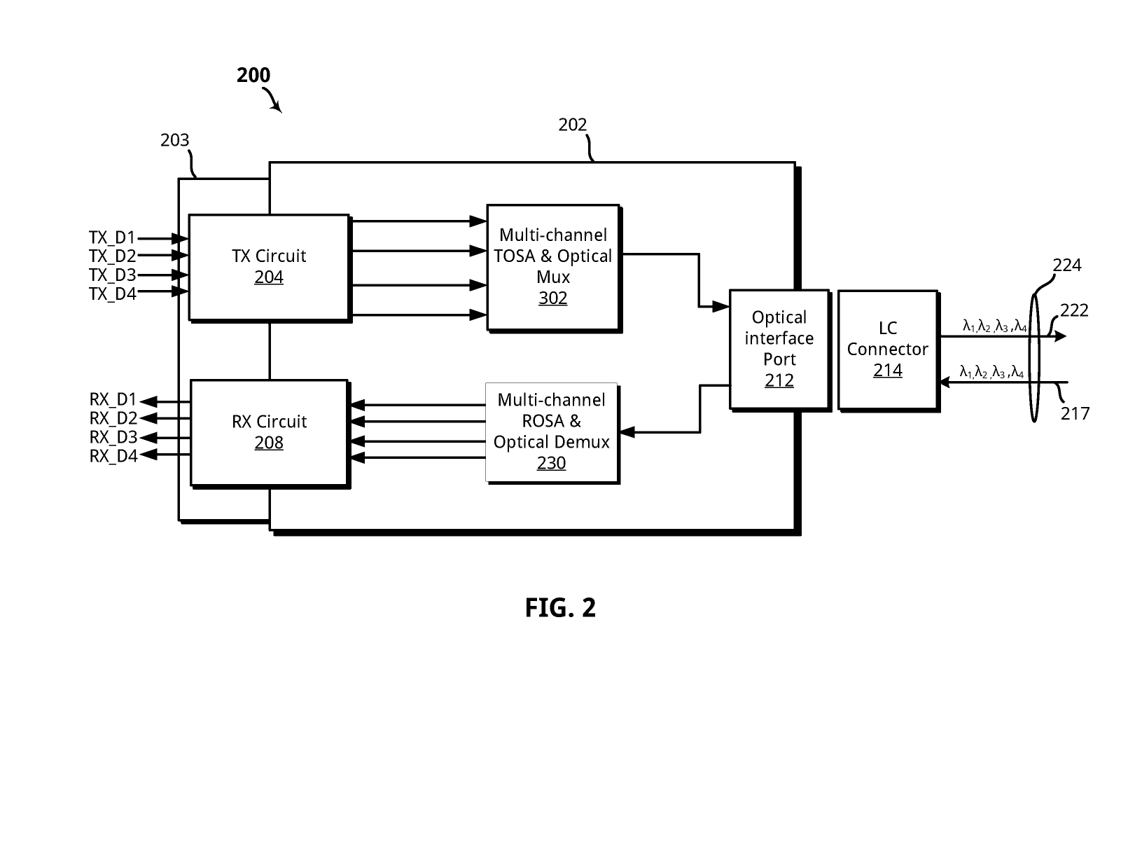

Now turning to FIG. 2, there is an optical transceiver 200 consistent with embodiments of the present disclosure. In more detail, the optical transceiver 200 transmits and receives four (4) channels using four different channel wavelengths (λ₁, λ₂, λ₃, λ₄) and may be capable of transmission rates of at least about 10 Gbps per channel. In one example, the channel wavelengths λ₁, λ₂, λ₃, λ₄ may be 1270 nm, 1290 nm, 1080 nm, and 1330 nm, respectively. The optical transceiver 200 may also be capable of transmission distances of 2 km to at least about 10 km. The optical transceiver 200 may be used, for example, in Internet data center applications or fiber to the home (FTTH) applications. In an embodiment, the optical transceiver 200 implements the specification SFF-8436 titled “QSFP+ 10 Gbs 4× PLUGGABLE TRANSCEIVER Rev 4.8” (hereinafter QSFP+), published on Oct. 31, 2013, by the Electronic Industries Alliance (EIA).

This embodiment of the optical transceiver 200 includes a multi-channel TOSA 302 for transmitting optical signals on different channel wavelengths and a multi-channel receiver optical subassembly (ROSA) 230 for receiving optical signals on different channel wavelengths. The multi-channel TOSA 302 and the multi-channel ROSA 230 are located in a transceiver housing 202. A transmit connecting circuit 204 and a receive connecting circuit 208 provide electrical connections to the multi-channel TOSA 302 and the multi-channel ROSA 230, respectively, within the housing 202 and communicate with external systems via data bus 203. In some cases, data bus 203 is a 38-pin connector that comports with physical connector QSFP standards and data communication protocols.

In any event, the transmit connecting circuit 204 is electrically connected to the electronic components (e.g., TO can laser packages) in the multi-channel TOSA 302, and the receive connecting circuit 208 is electrically connected to the electronic components (e.g., the photodiode packages) in the multi-channel ROSA 230. The transmit connecting circuit 204 and the receive connecting circuit 208 include at least conductive paths to provide electrical connections and may also include additional circuitry. The multi-channel TOSA 302 transmits and multiplexes multiple channel wavelengths and is coupled to an optical interface port 212. The optical interface port 212 may comprise an LC connector receptacle, although other connector types are also within the scope of this disclosure. For example, the optical interface port 212 may comprise a multi-fiber push on (MPO) connector receptacle.

In cases where the optical interface port 212 comprises a duplex, or bi-directional, LC receptacle, the LC connector receptacle provides optical connections to the multi-channel TOSA 302, and provides optical connections to the multi-channel ROSA 230. The LC connector receptacle may be configured to receive and be coupled to a mating LC connector 214 such that the transmit optical fiber 222 of the external fibers 224 optically couples to the multi-channel TOSA 302, and the receive optical fiber 217 of the external fibers 224 optically couples to the multi-channel ROSA 230.

The multi-channel TOSA 302 includes multiple TO can laser packages, discussed in greater detail below, and optics for producing assigned channel wavelengths and coupling the same into the transmit optical fiber 222. In particular, the lasers in the multi-channel TOSA 302 convert electrical data signals (TX_D1 to TX_D4) received via the transmit connecting circuit 204 into modulated optical signals transmitted over the transmit optical fiber 222. The lasers may include, for example, distributed feedback (DFB) lasers with diffraction gratings. The multi-channel TOSA 302 may also include monitor photodiodes for monitoring the light emitted by the lasers. The multi-channel TOSA 302 may further include one or more temperature control devices, such as a resistive heater and/or a thermoelectric cooler (TEC), for controlling a temperature of the lasers, for example, to control or stabilize the laser wavelengths.

The multi-channel ROSA 230 includes, for example, photodiodes, mirrors and filters that can de-multiplex different channel wavelengths in a received optical signal. The multi-channel ROSA 230 can detect, amplify, and convert such optical signals received from the external optical fibers 224, and can provide the converted optical signals as electrical data signals (RX_D1 to RX_D4) that are output via the receive connecting circuit 208. This embodiment of the optical transceiver 200 includes 4 channels and may be configured for coarse wavelength division multiplexing (CWDM), although other numbers of channels are within the scope of this disclosure.

Referring to FIG. 3, an example small form-factor (SFF) pluggable optical transceiver 300 with a multi-channel TOSA including TO can laser packages and multi-channel ROSA is described and shown in greater detail. The embodiment shown in FIG. 3 is one example of the optical transceiver 200 of FIG. 2 implemented in a small form-factor. For example, the optical transceiver 300 may implement the QSFP+ specification. The optical transceiver 300 includes the transceiver housing 202, a multi-channel TOSA 302 in one region of the housing 202, and a multi-channel ROSA 230 located in another region of the housing 202. As shown, the TO can laser package 304c of the multi-channel TOSA 302 directly contacts a surface of the ROSA 230. The multi-channel TOSA 302 is electrically connected to transmit flexible printed circuits (FPCs) 311 and optically coupled to the LC connector port 212 at an end of the housing 202. The multi-channel ROSA 230 is electrically connected to a receive flexible printed circuit (FPC) 309 and optically coupled to the LC connector port 212 at the end of the housing 202.

The multi-channel TOSA 302 includes TO can laser packages 304a, 304b, 304c, and 304d, with each containing optical components (or optical component assemblies) such as a laser diode. The TO can laser packages 304a-304d can provide, for example, output power from 1.85 mW to 2 W, although other output power is within the scope of this disclosure. The TO can laser packages 304a-304d may provide a broad spectrum of channel wavelengths, or configured to provide a relatively narrow spectrum of channel wavelengths such as a single channel wavelength. In some cases, the TO can laser packages 304a-304d provide center wavelengths 375 nm to 1650 nm, for example. In an embodiment, the TO can laser packages 304a-304d are Ø3.8 mm, Ø5.6 mm, or Ø9 mm TO cans, although other configurations are also within the scope of this disclosure. For instance, the TO can laser packages 304a-304d can include Ø9.5 mm and TO-46 cans.

The multi-channel TOSA 302 includes TO can laser packages 304a-304d within a recessed mounting region and coupled in a staggered manner, with TO can laser package 304c being disposed on an opposing sidewall to that of TO can laser packages 304a and 304b, as discussed in greater detail below. The multi-channel TOSA 302 may further include one or more recessed mounting regions, as discussed in greater detail below, that allow the multi-channel TOSA 302 to have a relatively reduced overall footprint within an optical transceiver housing.

Referring to FIG. 4A, with additional reference to FIG. 3, a cross-sectional view of an example housing 301 for the multi-channel TOSA 302 of FIG. 3 is shown in accordance with an embodiment of the present disclosure. As shown, the housing 301 includes first and second sidewalls 308 and 310, respectively, positioned on opposite sides of the housing 301 and extending generally in parallel along a longitudinal axis 303 from a first end 326 to a second end 327. The housing 301 further provides a cavity (or compartment) 316. The first sidewall 308 includes at least first and second sidewall openings 404a and 404b, and the second sidewall 310 includes at least a third sidewall opening 404c being positioned generally at a midpoint axis 307 of the housing 301. The midpoint axis 307 may extend from the first sidewall 308 to the second sidewall 310 and between the first and second sidewall openings 404a and 404b of the first sidewall 308. In some instances, the midpoint axis 307 may be located at a center of the housing 301. The first and second sidewall openings 404a and 404b transition from an external surface 408 of the first sidewall 308 and into the cavity 316. The third sidewall opening 404c transitions from an external surface 409 of the second sidewall 310 and into the cavity 316.

Referring to FIG. 4B, with additional reference to FIG. 4A, a side plan view of the housing 301 of FIG. 4A includes hidden lines generally illustrating various internal structural features of the housing 301, in accordance with an embodiment of the present disclosure. As shown, a first recessed mounting region 406 is defined by the external surface 408 of the first sidewall 308 and extends between the first end 326 and second end 327 of the housing 301. As further shown, the first end 326 may define a first step portion 450 and the second end 327 may define a second step portion 452. The first and second step portion 450 and 452 include a respective external surface 414 and 416 coupled to a respective one or more sidewalls 423 and 424 extending in an upward direction away from the external surface 408 of the first sidewall 308. The respective one or more sidewalls 423 and 424 may be adjacent to a portion of the external surface 408 that defines the first recessed mounting region 406. Accordingly, the first recessed region 406 extends between the first step portion 450 and the second step portion 452 and may include the first and second sidewall openings 404a and 404b.

The housing 301 may comprise a metal, an alloy, a plastic, or any other suitably rigid material. The housing 301 may comprise multiple segments or be formed from a single segment. In some cases, the step portions, such as the step portions 450, 452, 454, and 456, are integrally formed with the housing 301. For example, the step portions 450 and 452 may be formed by casting, milling, or other similar approaches. In other cases, the step portions 450, 452, 454, and 456 may be separate segments added to the housing 301 using, for example, press-fitting, welding, adhesives, or other approaches to fixation.

As also shown, the external surface (or surface) 414 of the first step portion 450 is offset from the external surface 408 of the first recessed mounting region 406 by a first offset distance 412. Likewise, the external surface (or surface) 416 of the second step portion 452 is offset from the external surface 408 of the first recessed mounting region by a second offset distance 418. The first offset distance 412 and the second offset distance 418 may measure substantially the same distance, or may measure different distances depending on a desired configuration. For example, the first offset distance 412 and/or the second offset distance 418 may measure 0.15 millimeters (mm), 0.3 mm, 0.45 mm, 0.6 mm, 1.0 mm, 1.5 mm, any range of measurements there between, or any other desired measurement. The first and second offset distances 412 and 418 of the first recessed mounting region 406 may result in a recessed mounting region thickness 420 being less than an overall step thickness 422. Stated differently, the reduction in thickness measured at 420 may be directly proportional to the offset distances 412 and 418 that, in a general sense, counter-sink the first recessed mounting region 406 into the housing 301. The first recessed mounting region 406 may be configured to couple optical components such as TO can laser assemblies to the first and second openings 404a and 404b. The first recessed mounting region 406 may be further configured to couple to other optical components by way of additional openings, such as the opening 460 of FIG. 4A, for example.

As further shown, the housing 301, and more particularly the second sidewall 310, may define the third and fourth step portions (or step regions) 454 and 456 and a second recessed mounting region 407 extending there between. The second recessed mounting region 407 may be defined by the external surface 409 of the second sidewall 310 that is offset from at least one of an external surface 442 or an external surface 444 of the third and fourth step regions 454 and 456 by a third offset distance 441 and/or fourth offset distance 443, respectively. The second recessed mounting region 407 may include the third sidewall opening 404c. Further discussion of the step portions 454 and 456 and second recessed mounting region 407 will generally be omitted herein for the sake of brevity because the step portions 454 and 456 and second recessed mounting region 407 may be configured to be substantially similar to the step portions 450 and 452 and the first recessed region 406. To this end, the third and fourth offset distances 441 and 443 may measure substantially the same as offset distances 412 and 418, although other embodiments are within the scope of this disclosure. For instance, the third and fourth offset distances 441 and 443 may measure substantially equal to each other, but may also measure less than or greater than the offset distances 412 and 418. In some cases, the first, second, third, and fourth offset distances 412, 418, 441, and 443 may measure substantially the same. Accordingly, in some embodiments, each of the first and second recessed mounting regions 406 and 407 may include substantially the same configuration such that the housing 301 is substantially symmetric about the longitudinal axis 303 and/or about the midpoint axis 307. However, such a symmetrical recessed mounting configuration is not necessarily required and each recessed mounting region 406 and 407 may include different configurations. Further, as shown collectively in the example embodiments of FIGS. 4B and 4C, the first offset distance 412, the second offset distance 418, the third offset distance 441, and/or the fourth offset distance 443 may measure equal to a thickness of the one or more welding rings 402a-402d. The first and second recessed mounting regions 406 and 407 are shown with a generally planar (or flat) configuration. However, the first and second recessed mounting regions 406 and 407 may be configured with non-planar surfaces and this disclosure should not be limited in this regard.

Turning to FIG. 4C, with additional reference to FIGS. 4A and 4B, first and second TO can laser packages 304a and 304b are shown coupled to the first and second sidewall openings 404a and 404b of the first sidewall 308, respectively, and a third TO can laser package 304c is coupled to the third sidewall opening 404c, with the third sidewall opening 404c opposing the first and second TO can laser packages 304a and 304b. As shown, the first recessed mounting region 406 allows the TO can laser packages 304a and 304b to couple to the housing 301 at a position below the surfaces 414 and 416 of the first and second step portions 450 and 452, respectively. Likewise, the second recessed mounting region 407 allows the third TO can laser assembly 304c to couple to the housing 301 in a similar fashion, e.g., below surfaces defining the third and fourth step portions 454 and 456. Thus, the overall width 434 of the TOSA 302 relative to, for example, the overall width 108 of the TOSA 110 of FIG. 1B, may be reduced. To this end, the resulting overall width 434 of the TOSA 302 may advantageously reduce the overall footprint of the same within a transceiver housing, such as the SFFP transceiver housing 202 of FIG. 3.

Continuing with FIG. 4C, the first recessed mounting region 406 may have a length 432 measured between the first and second step portions 450 and 452. The length 432 of the first recessed mounting region 406 may be such that the first and second openings 404a and 404b of the first sidewall 308 can receive TO can laser packages 304a and 304b. For example, the length 432 of the first recessed mounting region 406 may be based, at least in part, on a dimension 306 between adjacent TO can laser packages 304a and 304b. In some cases, the dimension 306 is at least about 3 mm, although other embodiments are within the scope of this disclosure. In other cases, dimension 306 is between 2 mm and 5 mm, for example. The dimension 306 provides component spacing greater than that of other approaches to TOSAs, such as the TOSA 100 shown in FIG. 1A. This increased dimension 306 advantageously allows laser welds to be formed without the cost and complexity normally associated with having tight tolerances between laser packages. For instance, an approach angle θ for the laser welding system may be within the range of 30° to 36°. In other cases, the range of the approach angles θ may include angles less than 30°. Therefore, the range of the approach angles θ may be greater for the TOSA 302 than for other approaches, such as the TOSA 100 of FIG. 1A.

Although FIG. 4C shows the second recessed mounting region 407 having a length substantially equal to the length 432 of the first recessed mounting region 406, other embodiments are within the scope of this disclosure. For example, the length of the second recessed mounting region 407 may be greater than or less than the length 432.

Continuing with FIG. 4C, with additional reference to FIG. 4B, the fourth TO can laser package 304d can be coupled to the housing 301 at a third sidewall 312, with the third sidewall 312 adjoining the first and second sidewalls 308 and 310. The third sidewall 312 includes a fourth sidewall opening 404d. The housing 301 may further include an optical coupling receptacle 324 coupled to a fourth sidewall 313 by way of a fifth sidewall opening 404e, the fifth sidewall opening 404e being opposite the fourth sidewall opening 404d.

As shown, the first and third step portions 450 and 454 advantageously provide structural support for the purposes of coupling to the fourth TO can laser package 304d. For example, the overall step thickness 422 (FIG. 4B) may be of sufficient size such that the fourth TO can laser package 304d can be coupled to the housing 301 by way of the fourth sidewall opening 404d. Similarly, the second and fourth step portions 452 and 456 may provide the housing 301 with a thickness sufficient to support the coupling of the optical coupling receptacle 324 to the housing 301 by way of the fifth sidewall opening 404e. Stated differently, step portions 450, 452, 454, and 456 of the housing 301 may be sized with dimensions that support attachment of laser packages/optical components at ends of the housing 301. To this end, the dimensions of a particular optical component/assembly may determine the particular overall step thickness 422 of the optical housing.

Referring to FIG. 4D, there is a cross-sectional view of the multi-channel TOSA 302 of FIG. 3 in accordance with an embodiment. As shown, the housing 301 also forms the cavity 316, or compartment, that defines a light path 322 that extends through filters 318a, 318b, and 318c, respectively, before encountering a focusing lens 320. The filters 318a-318c are positioned on filter holders 319a, 319b, and 319c, respectively. The optical coupling receptacle 324 extends from the second end 327 for optically coupling the light of TO can laser packages 304a-304d to the transmit optical fiber 222. Thus, the filters 318a-318c, the lens 320, and the optical coupling receptacle 324 are generally aligned or positioned along a longitudinal axis provided by the light path 322. This combination of filters may be accurately described as multiplexing optics and can provide coarse wavelength division multiplexing (CWDM) in an optical signal. Multiplexing different channel wavelengths using this configuration will now be discussed in the context of a four (4) channel TOSA configuration, such as shown in FIG. 4C.

Each of the TO can laser packages 304a-304d can be associated with different channel wavelengths. For example, the channel wavelengths (λ1, λ2, λ3, λ4) associated with TO can laser packages 304a-304d may be 1290 nm, 1330 nm, 1310 nm, and 1270 nm, respectively. To multiplex these different channel wavelengths into a signal optically coupled to transmit optical fiber 222, the housing includes TO can laser package 304d configured to direct light coaxially along light path 322 into the cavity (or compartment) 316. In turn, the filter 318a positioned adjacent the TO can laser package 304d can provide wavelength-dependent transmission such that only the channel wavelength λ1, associated with the TO can laser package 304d, passes through filter 318a. The filter 318a may also provide wavelength-dependent reflectivity such that only channel wavelength λ2 is reflected therefrom. At this point, the light along light path 322 includes, essentially, channel wavelengths λ1 and λ2. After those channel wavelengths pass through filter 318c, they converge with wavelength λ3, which is provided by the filter 318c reflecting only channel wavelength λ3 from the light directed by TO laser package 304c. At this point the light along light path 322 now includes, essentially, channel wavelengths λ1, λ2, and λ3. After those channel wavelengths pass through filter 318b, they converge with channel wavelength λ4, which is provided by the filter 318b reflecting only channel wavelength λ4 from the light directed by TO laser package 304b. As shown, collimating lenses 305a-305d collimate light emitted by each TO can laser package. Thus, at focusing lens 320, the resulting optical signal includes multiple different multiplexed channel wavelengths (e.g., λ1, λ2, λ3, λ4) and is optically coupled to the transmit optical fiber 222.

The multi-channel TOSA 302 may include additional channels and is not necessarily limited to the four (4) shown in FIG. 4D. That is, additional TO can laser packages may be disposed along the sidewalls of housing 301. For instance, the first sidewall 308 may include 3 or more TO can laser packages. Each of those TO can laser packages may be disposed with spacing similar to the embodiment shown in FIG. 4D. On the opposing sidewall, such as second sidewall 310, TO can laser packages may be coupled such that they are disposed generally coextensive or otherwise overlapping with the area between each of the TO can laser packages of the first sidewall 308. This staggered/opposing arrangement may be repeated for N number of optical channels, depending on a desired configuration.

Moreover, the placement of the TO can laser packages are not necessarily limited to the embodiment shown. For example, TO can laser package 304c may be coupled to a sidewall that is perpendicular (or at a right angle) to the TO can laser packages 304a and 304b.

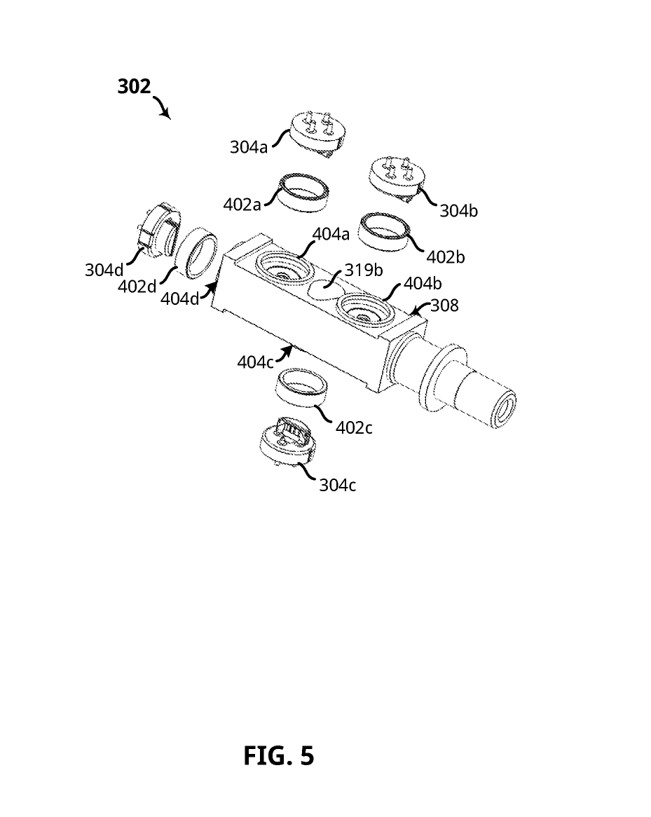

Referring now to FIG. 5, there is an exploded view of the multi-channel TOSA 302, in accordance with an embodiment of the present disclosure. As shown, each of the TO can laser packages 304a-304d include an associated welding ring 402a-402d, respectively. These welding rings 402a-402d allow the TO can laser packages 304a-304d to be placed over and coupled to sidewall openings 404a-404d, respectively. As previously discussed, laser welding is one approach that is particularly well suited for ensuring optical efficiency (power) and reliable operation over a lifetime of the multi-channel TOSA 302.

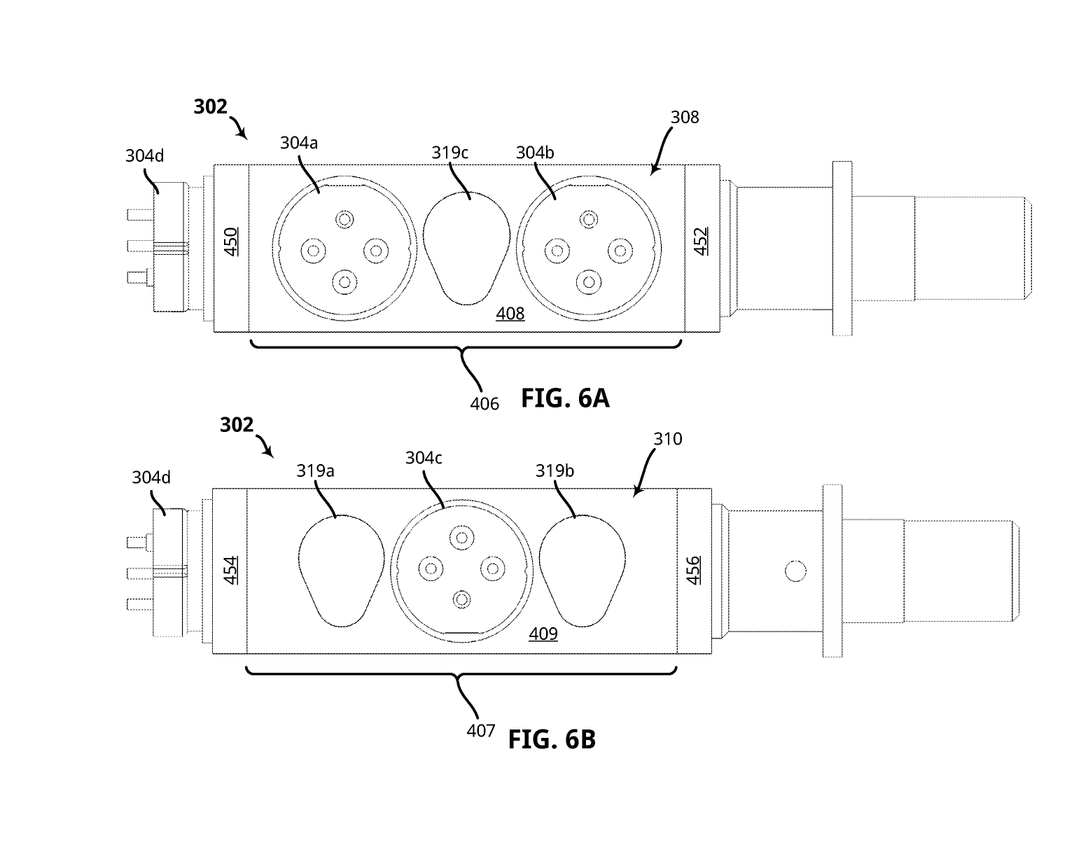

Note that an outer surface of the filter holder 319b is substantially flat and co-planar with an outer surface of the first sidewall 308. This advantageously provides a generally flat area that does not otherwise obstruct access when attaching TO can laser packages 304a and 304b during manufacturing. FIG. 6A further illustrates how the filter holder 319c is positioned between the first and second step portions 450 and 452 and is substantially coplanar with at least a portion of the external surface 408 of the first sidewall 308 that defines the first recessed mounting region 406. The filter hold 319c resides between TO can laser packages 304a and 304b. On the other hand, FIG. 6B illustrates how filter holders 319a and 319b are between the third and fourth step portions 454 and 456, are generally flat, and generally do not obstruct access to the area around TO can laser package 304c along at least a portion of the external surface 409 of the second sidewall 310 that defines the second recessed region 407. As shown in FIG. 6A and 6B, the multi-channel TOSA 302 may have a relatively small size. In some embodiments, the long axis of the housing may be 15 mm, or less.

The multi-channel TOSA 302 may be formed as one piece or as multiple pieces attached together. Although the illustrated embodiment shows the multi-channel TOSA 302 with a particular shape, other shapes and configurations are also possible. In other embodiments, for example, the housing 301 may be generally cylindrical.

### Further Example Embodiments

In accordance with an aspect of the present disclosure a transmitter optical subassembly (TOSA) is disclosed. The TOSA including a housing including at least a first sidewall and a second sidewall disposed on opposite sides of the housing relative to each other, the first and second sidewalls extending along a longitudinal axis from a first end to a second end of the housing, wherein the housing further includes a first step portion defined by the first sidewall and disposed adjacent the first end of the housing, a first recessed mounting region disposed adjacent the first step portion, the first recessed mounting region defined by an external surface of the first sidewall that extends along the longitudinal axis towards the second end of the housing, the external surface defining the first recessed mounting region being offset from a surface defining the first step portion by a first offset distance, and wherein the first recessed mounting region includes at least a first sidewall opening, the first sidewall opening configured to couple to an optical component assembly.

In accordance with another aspect of the present disclosure an optical transceiver is disclosed. The optical transceiver comprising a transceiver housing, a transmitter optical subassembly (TOSA) having a plurality of transistor outline (TO) can laser packages coupled thereto and located in the transceiver housing for transmitting optical signals at different channel wavelengths, the TOSA comprising a TOSA housing including at least a first sidewall and a second sidewall disposed on opposite sides of the TOSA housing relative to each other, the first and second sidewalls extending along a longitudinal axis from a first end to a second end of the TOSA housing, wherein the TOSA housing further includes first and second step portions defined by the first sidewall and a first recessed mounting region extending there between, the first recessed mounting region being defined by an external surface of the first sidewall that is offset from a surface defining the first step portion by a first offset distance, wherein the first recessed mounting region includes at least a first sidewall opening and a second sidewall opening, each of the first and second sidewall openings to couple to respective TO can laser packages, and at least first and second TO can laser packages coupled to the first and second sidewall openings of the first sidewall, respectively, and a multi-channel receiver optical assembly (ROSA) located in the transceiver housing for receiving optical signals at different channel wavelengths.

In accordance with yet another aspect of the present disclosure an optical transceiver is disclosed. The optical transceiver including a housing including at least a first sidewall and a second sidewall disposed on opposite sides of the housing relative to each other, the first and second sidewalls extending along a longitudinal axis from a first end to a second end of the housing and providing a cavity therebetween, wherein the housing comprises a first and second step portion defined by the first sidewall and a first recessed mounting region disposed there between, the first recessed mounting region being defined by an external surface of the first sidewall that is offset from a surface defining the first step portion by a first offset distance, wherein the first recessed mounting region includes at least a first sidewall opening and a second sidewall opening to couple to respective TO can laser packages, a third and fourth step portion defined by the second sidewall and a second recessed mounting region disposed there between, the second recessed mounting region being defined by an external surface of the second sidewall that is offset from a surface defining the third step portion by a second offset distance, wherein the second recessed mounting region includes at least one third sidewall opening to couple to respective TO can laser packages, and first, second, and third transistor outline (TO) can laser packages coupled to each of the first, second, and third sidewall openings, respectively.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. Modifications and substitutions by one of ordinary skill in the art are considered to be within the scope of the present disclosure, which is not to be limited except by the following claims.

What is claimed is:

1. A transmitter optical subassembly (TOSA), the TOSA comprising:
a housing including at least a first sidewall and a second sidewall disposed on opposite sides of the housing relative to each other, the first and second sidewalls extending along a longitudinal axis from a first end to a second end of the housing, wherein the housing further includes:
a first step portion defined by the first sidewall and disposed adjacent the first end of the housing;
a first recessed mounting region disposed adjacent the first step portion, the first recessed mounting region defined by an external surface of the first sidewall that extends along the longitudinal axis towards the second end of the housing, the external surface defining the first recessed mounting region being offset from a surface defining the first step portion by a first offset distance; and
wherein the first recessed mounting region includes at least a first sidewall opening, the first sidewall opening configured to couple to an optical component assembly.

2. The TOSA of claim 1, further comprising a second step portion defined by the first sidewall and disposed adjacent the second end of the housing, wherein the first recessed mounting region extends between the first and second step portions.

3. The TOSA of claim 1, wherein the first recessed mounting region further includes a second sidewall opening to couple to an optical component assembly, and wherein the second sidewall includes a third sidewall opening to couple to an optical component assembly, the third sidewall opening being positioned generally at a midpoint between the first and second sidewall openings of the first recessed mounting region.

4. The TOSA of claim 3, further comprising a plurality of TO can laser packages, each of the plurality TO can laser packages being coupled to a respective one of the first, second, or third sidewall openings.

5. The TOSA of claim 4, further comprising a third sidewall at the first end of the housing and adjoining the first and second sidewalls, the third sidewall including a fourth sidewall opening and a fourth TO can laser package coupled thereto.

6. The TOSA of claim 2, wherein the housing further comprises a third and fourth step portion defined by the second sidewall and a second recessed mounting region disposed therebetween, the second recessed mounting region being defined by an external surface of the second sidewall that is offset from a surface defining the third step portion and/or a surface defining the fourth step portion by a second offset distance.

7. The TOSA of claim 6, wherein the second recessed mounting region includes a third sidewall opening to couple to an optical component assembly.

8. The TOSA of claim 6, wherein the first and second offset distances measure substantially the same.

9. The TOSA of claim 8, wherein the first and second offset distances each measure about 0.3 millimeters.

10. The TOSA of claim 1, wherein the TOSA is configured to generate at least four different wavelength division multiplexed (WDM) channel wavelengths.

11. An optical transceiver comprising:
a transceiver housing;
a transmitter optical subassembly (TOSA) having a plurality of transistor outline (TO) can laser packages coupled thereto and located in the transceiver housing for transmitting optical signals at different channel wavelengths, the TOSA comprising:
a TOSA housing including at least a first sidewall and a second sidewall disposed on opposite sides of the TOSA housing relative to each other, the first and second sidewalls extending along a longitudinal axis from a first end to a second end of the TOSA housing, wherein the TOSA housing further includes:
first and second step portions defined by the first sidewall and a first recessed mounting region extending there between, the first recessed mounting region being defined by an external surface of the first sidewall that is offset from a surface defining the first step portion by a first offset distance;
wherein the first recessed mounting region includes at least a first sidewall opening and a second sidewall opening, each of the first and second sidewall openings to couple to respective TO can laser packages; and
at least first and second TO can laser packages coupled to the first and second sidewall openings of the first sidewall, respectively; and
a multi-channel receiver optical assembly (ROSA) located in the transceiver housing for receiving optical signals at different channel wavelengths.

12. The optical transceiver of claim 11, wherein the second sidewall includes at least a third sidewall opening to couple to an optical component assembly, the third sidewall opening being positioned generally at a midpoint between the first and second sidewall openings of the first recessed mounting region.

13. The optical transceiver of claim 12, further comprising a third TO can laser package coupled to the third sidewall opening.

14. The optical transceiver of claim 11, further comprising a third sidewall at the first end and adjoining the first and second sidewalls, the third sidewall including a fourth sidewall opening and a fourth TO can laser package coupled thereto.

15. The optical transceiver of claim 11, wherein the TOSA housing further comprises a third and fourth step portion defined by the second sidewall and a second recessed mounting region disposed there between, the second recessed mounting region being defined by an external surface of the second sidewall that is offset from a surface defining the third step portion and/or a surface defining the fourth step portion by a second offset distance.

16. The optical transceiver of claim 15, wherein the first and second offset distances measure substantially the same.

17. A transmitter optical subassembly (TOSA) housing comprising:
a housing including at least a first sidewall and a second sidewall disposed on opposite sides of the housing relative to each other, the first and second sidewalls extending along a longitudinal axis from a first end to a second end of the housing and providing a cavity therebetween, wherein the housing comprises:
a first and second step portion defined by the first sidewall and a first recessed mounting region disposed there between, the first recessed mounting region being defined by an external surface of the first sidewall that is offset from a surface defining the first step portion by a first offset distance;
wherein the first recessed mounting region includes at least a first sidewall opening and a second sidewall opening to couple to respective TO can laser packages;
a third and fourth step portion defined by the second sidewall and a second recessed mounting region disposed there between, the second recessed mounting region being defined by an external surface of the second sidewall that is offset from a surface defining the third step portion by a second offset distance;
wherein the second recessed mounting region includes at least one third sidewall opening to couple to respective TO can laser packages; and
first, second, and third transistor outline (TO) can laser packages coupled to each of the first, second, and third sidewall openings, respectively.

18. The TOSA housing of claim 17, further comprising a third sidewall at the first end and adjoining the first and second sidewalls, the third sidewall including a fourth sidewall opening and a fourth TO can laser package coupled thereto.

19. The TOSA housing of claim 17, wherein the third sidewall opening is positioned generally at a midpoint between the first and second sidewall openings of the first recessed mounting region.

20. The TOSA housing of claim 17, wherein the first and second offset distances measure substantially the same.
